(19) United States
(12) Patent Application Publication
(10) Pub. No.: US 2025/0087587 A1
(43) Pub. Date: Mar. 13, 2025

(54) EMBEDDED ORGANIC BRIDGE COMPONENT FOR SEMICONDUCTOR PACKAGES

(71) Applicant: Intel Corporation, Santa Clara, CA (US)

(72) Inventor: Jeremy D. Ecton, Gilbert, AZ (US)

(73) Assignee: Intel Corporation, Santa Clara, CA (US)

(21) Appl. No.: 18/465,779

(22) Filed: Sep. 12, 2023

(51) Int. Cl. H01L 23/538; H01L 23/498; H01L 23/522; H01L 23/528

(52) U.S. Cl. CPC H01L 23/5381; H01L 23/49816; H01L 23/5226; H01L 23/5283

(57) ABSTRACT

Architectures and process flows for an embedded organic bridge component for semiconductor packages. The bulk of the substrate package fabrication can be done using conventional processing steps to meet core geometries (e.g., 9/12) with associated equipment and clean room protocols. Separately the organic bridge component is fabricated to embed into the substrate package at a location where the high-speed input/output (I/O) performance and high-density (HD) geometry are required. The organic bridge component is fabricated as required to meet the HD geometry (e.g., 3/3, or less). During assembly, the embedded organic bridge component can be attached into a cavity in the substrate package.

### BACKGROUND

The demand for miniaturization of form factor and increased levels of integration for high performance are driving sophisticated packaging approaches in the semiconductor industry. Reliable connections between die in a semiconductor package that also deliver a desired bandwidth presents a technical challenge. Accordingly, continued improvements to semiconductor package architectures and methodologies that support high-speed signaling and miniaturization are desired.

### BRIEF DESCRIPTION OF THE DRAWINGS

FIG. 1 illustrates an example semiconductor package that implements at least one embedded organic bridge component, in accordance with various embodiments.

FIG. 2 provides simplified cross-sectional illustrations of a semiconductor package core patterned with thick seed and redistribution layers (RDL), in accordance with various embodiments.

FIG. 3 provides a simplified cross-sectional illustration of embodiments in FIG. 2 with additional RDL built up on upper and lower surfaces, in accordance with various embodiments.

FIG. 4 illustrates creating a cavity in the upper surface of the semiconductor package core, in accordance with various embodiments.

FIG. 5 illustrates placing an organic bridge component into the cavity in the substrate package and attaching it therein.

FIG. 6 is a simplified illustration of a semiconductor package assembly that implements an embodiment of the embedded organic bridge component, in accordance with various embodiments.

FIG. 7 is a simplified illustration of another semiconductor package assembly that implements an embedded organic bridge component having different features, in accordance with various embodiments.

FIG. 8 is a simplified illustration of another semiconductor package assembly that implements an embedded organic bridge component having different features, in accordance with various embodiments.

FIG. 9 is a simplified illustration of another semiconductor package assembly that implements an embedded organic bridge component having different features, in accordance with various embodiments.

FIG. 10 is a simplified illustration of another semiconductor package assembly that implements an embedded organic bridge component having different features, in accordance with various embodiments.

FIG. 11 illustrates an example method for manufacturing and implementing an embedded organic bridge component, in accordance with various embodiments.

FIG. 12 is a top view of a wafer and dies that may be included in a microelectronic assembly, in accordance with any of the embodiments disclosed herein.

FIG. 13 is a simplified cross-sectional side view showing an implementation of an integrated circuit on a die that may be included in various embodiments, in accordance with any of the embodiments disclosed herein.

FIG. 14 is a cross-sectional side view of a microelectronic assembly that may include any of the embodiments disclosed herein.

FIG. 15 is a block diagram of an example electrical device that may include any of the embodiments disclosed herein.

### DETAILED DESCRIPTION

The integration of multiple integrated circuit (IC) components in semiconductor packaging to meet the expectations of high-speed signaling often involves the technical challenge of relying on one or more bridge components. The bridge components may support finer pitches than in the surrounding semiconductor substrate package and can be dedicated for communication between two heterogeneous IC dies.

A proposed technical solution includes separately fabricating a silicon component with high density interconnect and fine pitch geometries, and then embedding the silicon component into the substrate package (the embedded bridge approach). However, these silicon components can be costly. Another proposed solution includes fabricating the high-density interconnects directly in the substrate package (i.e., high density patterning). However, achieving an appropriate yield with substrate packages while also meeting the stringent warpage requirements for high resolution exposure in a substrate package remains a technical challenge.

Embodiments described herein provide a technical solution to these technical challenges in the form of architectures and process flows for an organic embedded bridge component for semiconductor packages. Such an approach can be used in semiconductor substrate packages that integrate heterogeneous dies configured for high speed signaling, including electronic integrated circuits and photonic integrated circuits.

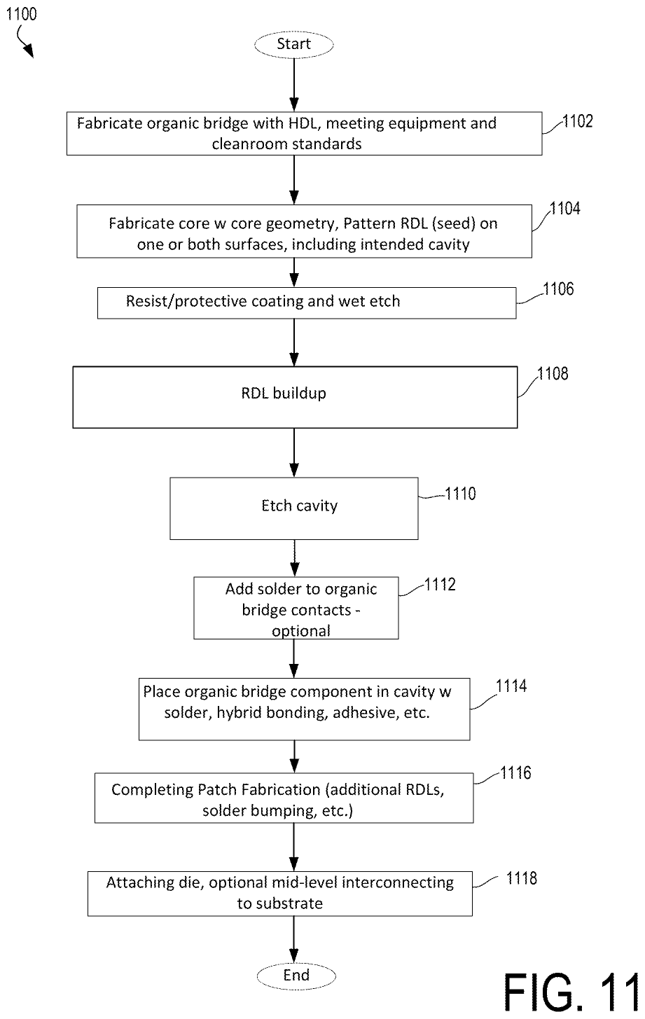

Advantageously, embodiments enable that the majority of the substrate package fabrication can be done using conventional processing steps to meet core geometries, with associated equipment and clean room standards, while the region of the substrate package needing the high-speed input/output (I/O) performance and high-density (HD) geometry can be reserved for the organic bridge component; separately (referenced at 1102 FIG. 11), the organic bridge component is fabricated in a stricter clean room environment with more precise equipment, such that the HD geometry (e.g., 3/3) can be achieved. During assembly, the embedded organic bridge component can be placed in a cavity of the substrate package. These concepts are developed in more detail below.

Example embodiments are hereinafter described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

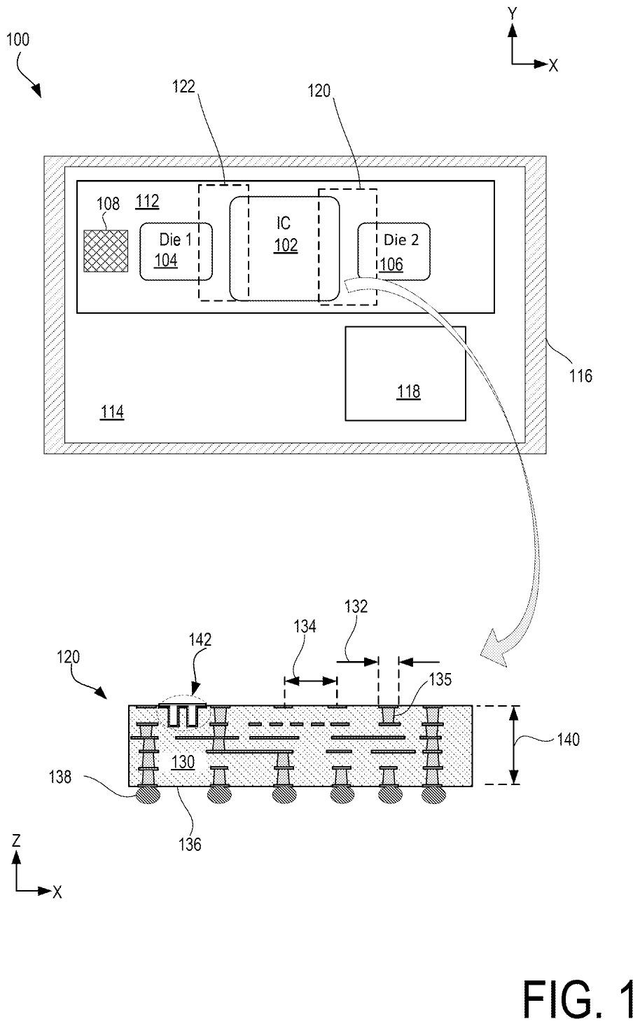

The non-limiting example in FIG. 1 is a semiconductor package 100 that integrates multiple heterogenous dies and implements at least one organic embedded bridge component. The semiconductor package 100 comprises an integrated circuit (IC) die 102, a first die 104, and a second die 106. The first die 104 and/or the second die 106 may be another electronic integrated circuit die (EIC) or a photonic integrated circuit die (PIC). In the case that the first die 104 or the second die 106 is a PIC, it may be in operable communication with an optional fiber array unit. In the non-limiting example of FIG. 1, the PIC die 104 is shown operably connected to fiber array unit (FAU) 108. The dies may be attached to a substrate 112. In various embodiments, the substrate 112 may comprise a printed circuit board, thin-film substrate, or another suitable substrate. In other package assembly and/or device embodiments, the substrate 112 may further be attached to a printed circuit board (PCB) 114; and in further embodiments, the multi-die assembly may include additional IC die, represented generally as die 118. As may be appreciated, this arrangement of die is just one example embodiment, in other multi-die assemblies, there may be more or less PIC die, more or less FAU components, more or less ICs, and the dies may be arranged in any pattern (e.g., square (e.g., 2×2, 4×4, 6×6), rectangular (e.g., 2×4, 3×5, 4×7)).

In various embodiments, such as when implemented in a packaged assembly or a device, the die in the semiconductor package 100 may be overmolded with an encapsulant 116. The encapsulant 116 can comprise a molding compound, dielectric materials, metal, ceramic, plastic, or a combination thereof. Additionally, a thermal management solution (not shown) comprising a cooling component such as a vapor chamber, heat pipe, heat sink, or liquid-cooled cold plate may be attached to a semiconductor package 100. As part of a thermal management solution, a thermal conduction layer interface material (TIM) may be located over the die 102. The TIM can be any suitable material, such as a silver particle-filled thermal compound, thermal grease, phase change materials, indium foils, or graphite sheets. The thermal management solution can be a conformal solution that accommodates differences in heights of the integrated circuit dies for which the thermal management solution provides cooling. For example, a thermal management solution can comprise a substantially planar cooling component with TIMs of varying thickness between the cooling component and the integrated circuit dies. In another example, the cooling component is non-planar, and the profile of the cooling component can vary with the thickness of the integrated circuit dies for which the cooling component provides cooling. In such embodiments, the TIM can be of substantially uniform thickness between the cooling component and the integrated circuit dies of varying thicknesses. Thermal management solutions can also include an integrated heat spreader.

The die 102, 104, 106, and 118, may be unpackaged integrated circuit die, and may alternatively be referred to as chips, chiplets, chip complexes, or chiplet complexes. The PICS employ at least some optical communication, and the fiber array units (FAUs) implement optical switching functionality. While the terms die, chip, and chiplet may be used interchangeably, the term chiplet is sometimes used to refer to an integrated circuit die that implements a subset of the functionality of a larger integrated circuit component. Although the illustration depicts the chiplets as having uniform dimensions, in practice, chiplet dimensions (lateral dimensions, as well as thickness) and shape can vary among chiplets; moreover, the chiplets may vary by type/functionality (e.g., compute, memory, I/O, power management (controlling the delivery of power and/or providing power to components)). Any integrated circuit die, chip, or chiplet can implement any portion of the functionality of any processor unit described or referenced herein. Furthermore, a semiconductor package 100 can have any shape, such as a substantially square shape, substantially rectangular shape, or substantially circular shape. The dashed lines narrow the focus areas of the substrate package 112 that includes an embedded organic bridge component 120, 122.

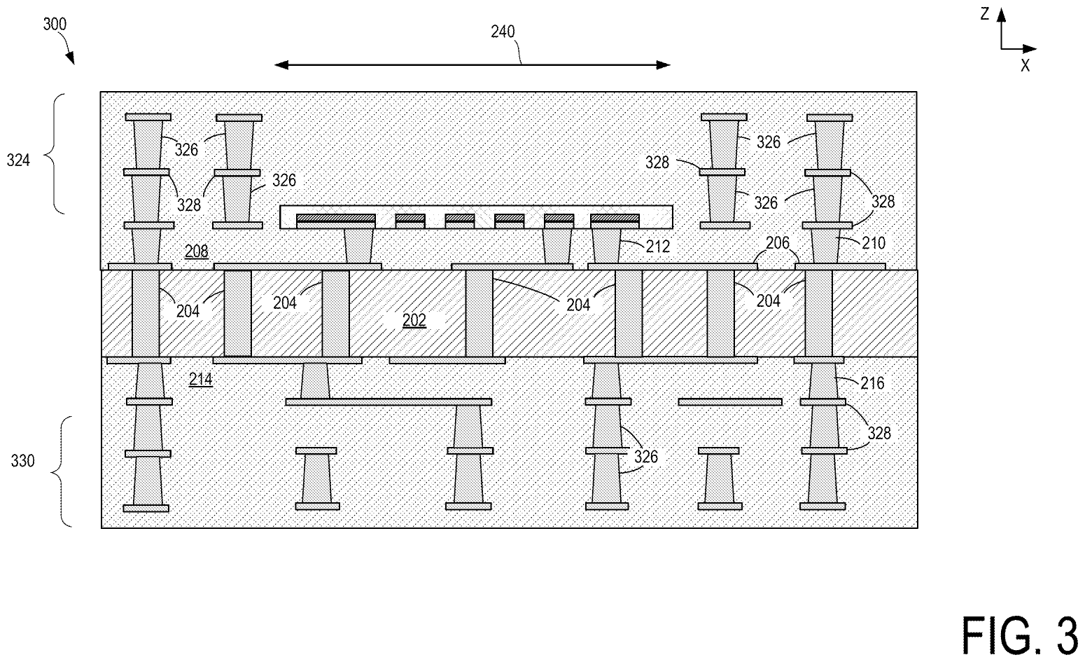

Embodiments of the disclosed embedded organic bridge component 120 are configured to be in the substrate package 112 (specifically, in a cavity in the substrate package, as described in more detail below). Unlike other bridge solutions, the provided embedded organic bridge component 120 may be fabricated using a dielectric material with silicon fillers, or Ajinomoto build-up film (ABF). The embedded organic bridge component 120 can comprise the same dielectric material (e.g., in the second region 130) as that of the substrate package in which it is located (see, e.g., the dielectric materials discussion in connection with FIG. 3, dielectric layers 324 and 330).

As used herein, redistribution layers (RDL) are metal or conductive traces or interconnects that connect or provide electrical paths between one region in a semiconductor package to another region and are sufficient for electrical communication and/or for supplying power and ground. Embodiments of the embedded organic bridge component 120 can comprise the same trace or RDL materials; however, they implement a high density or HD geometry, defined herein as a 3/3 or less geometry, meaning that the conductive traces 135 have a (interconnect line width) width 132 of three microns or less, and are spaced from each other (spacing 134) at three microns or less. In contrast, the surrounding substrate package 112 may implement a larger, “core geometry,” such as a 9/12 geometry (meaning a conductive trace width of 9 microns and a spacing of 12 microns). Additionally, as may be appreciated, the dimensions of the embedded organic bridge component 120 are smaller than the corresponding dimensions of the substrate package. The embedded organic bridge component 120 thickness 140 (or height in the Z-X illustrations) is in a range of about 20% of the substrate package thickness to about 70% of the substrate package thickness, wherein about means plus or minus 10%. The lower surface 136 of the embedded organic bridge component 120 has conductive contacts, also at the HD geometry, on which solder bumps 138 can be placed for attaching into a cavity in a substrate package 112.

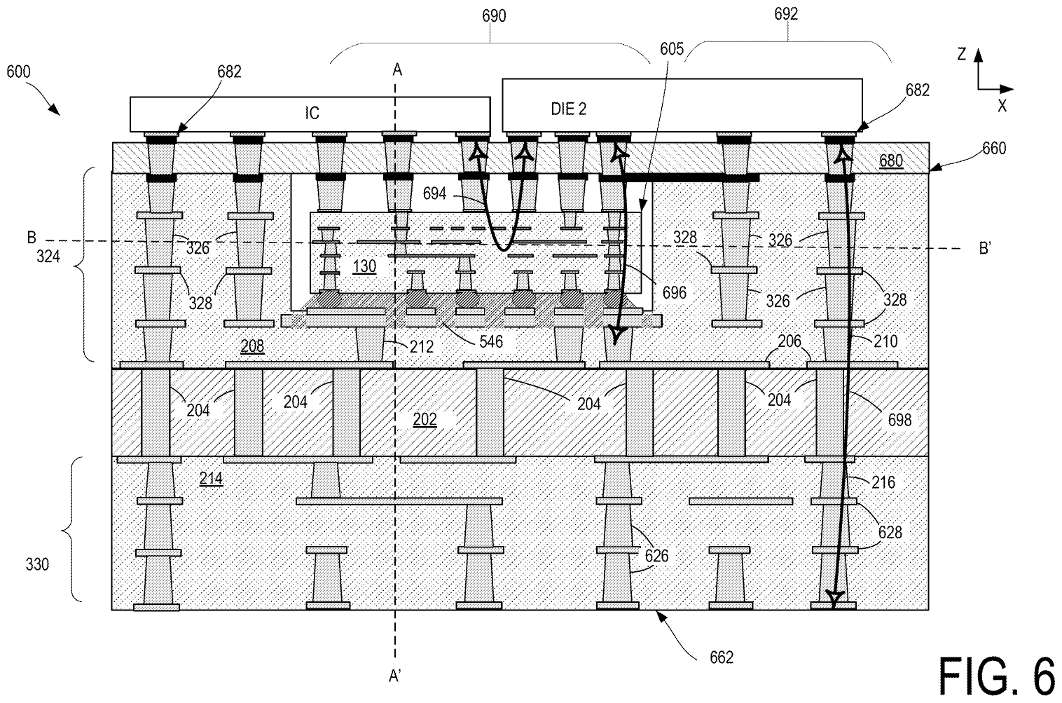

Therefore, to identify embodiments of this disclosure, one would look at a portion of a substrate package 112, e.g., using SEM or TEM (transmission electron microscopy) and identify a region in which there is a transition in scale of the RDL or trace width and trace spacings, from the core geometry to the HD geometry, and confirm that the material of the region having the HD geometry comprises a dielectric material. As mentioned, the dielectric material of the second region 130 of the embedded organic bridge component 120 may or may not be the same as a dielectric material of the substrate package 112. Depending on the view in the SEM or TEM, one might observe the solder bumps 138 at the lower surface 136, which could be somewhere mid-substrate package 112 (in the Z direction, as shown in FIGS. 6-8).

In some embodiments of the embedded organic bridge component 120, in addition to the fine pitch or HD routing and interconnect described above, one or more additional electrical components 142 are implemented. A non-limiting example of an additional electrical component 142 that can be implemented in the embedded organic bridge component 120 is a trench capacitor. A trench capacitor may be identified by a silicon dioxide layer over an air gap/cavity, the cavity having walls of polysilicon and an oxide-nitride-oxide (ONO) layer (this would be on a side or Z-X profile, as shown).

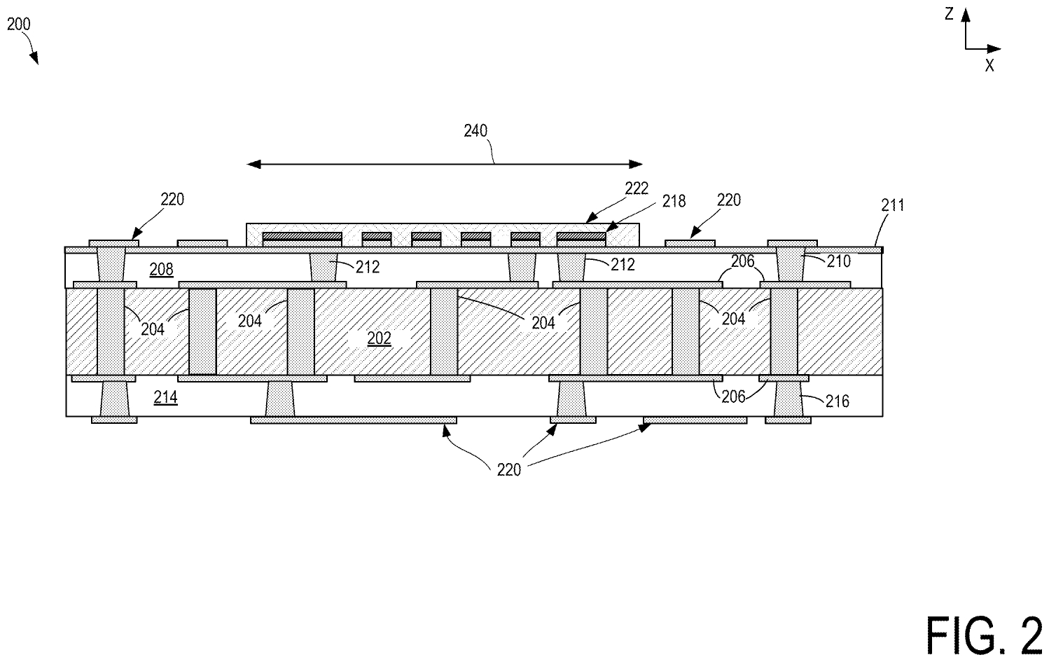

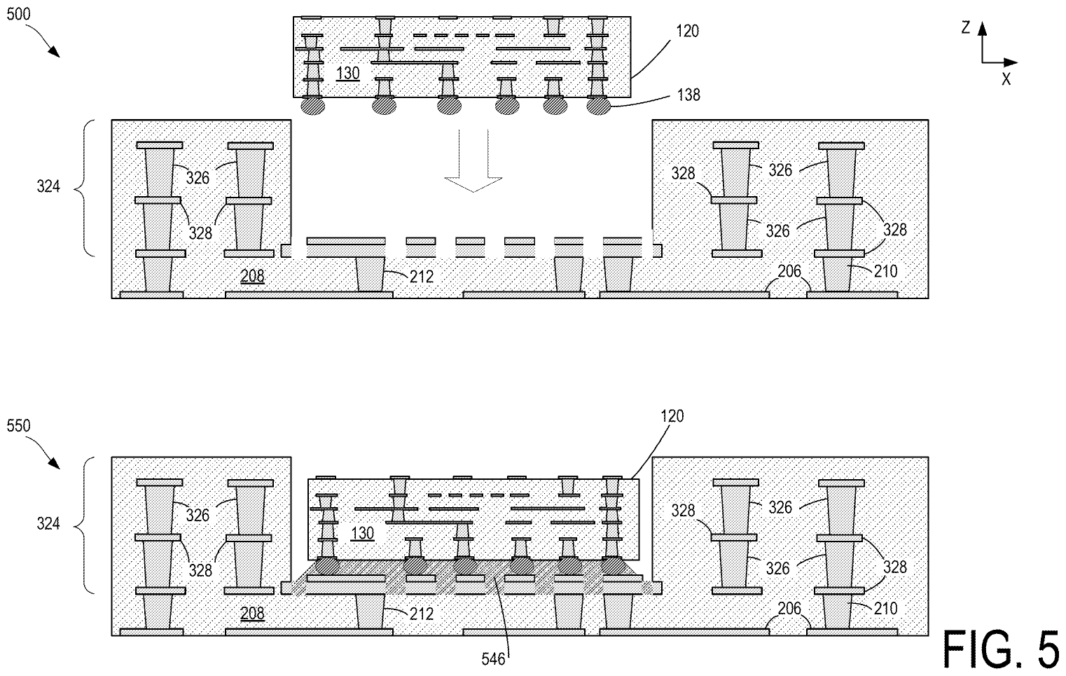

FIGS. 2-5 illustrate various stages of fabrication of a substrate package for implementing an embedded organic bridge component 120. This substrate view is sometimes referred to as a “substrate patch.” FIG. 5 illustrates placing the embedded organic bridge component 120 into a cavity in the substrate package and attaching it therein. FIGS. 6-10 illustrate some non-limiting examples of a package assembly in which various embodiments of the embedded organic bridge component are employed. FIG. 11 provides a process flow for creating embodiments described herein.

As mentioned, embodiments of the substrate package (substrate 112) often include a core 202 layer, as illustrated in FIG. 2. The core is fabricated with the core geometry, and redistribution layers (RDL) are patterned on one or both surfaces (at 1104). In various embodiments, the core 202 comprises glass (as used herein, glass can be an alkali-free alkaline earth boro-aluminosicilate glass, such as a glass comprising aluminum, oxygen, boron, silicon, and an alkaline-earth metal (e.g., beryllium, magnesium, calcium, strontium, barium, radium, such as a glass comprising SiO₂, Al₂O₃, B₂O₃, and MgO), or a photosensitive glass (photomachineable or photostructurable glass). In some embodiments, a photosensitive glass can be a glass that belongs to the lithium-silicate family of glass (e.g., a glass comprising lithium, silicon, and oxygen) comprising metallic particles, such as gold, silver, or other suitable metallic particles. The core 202 may comprise multiple glass sheets bonded together with an adhesion layer. In various embodiments, the core 202 may have a thickness that ranges from about 20 microns to about 1 millimeter, wherein about means plus or minus 10%.

In other embodiments, the core 202 layer may comprise epoxy or a combination of epoxy and glass. As used herein, “epoxy” may include epoxy resin, a fiberglass-reinforced epoxy resin, an epoxy resin with inorganic fillers, a ceramic material, or a polymer material such as polyimide.

The core 202 may be sandwiched between dielectric layers that include respective redistribution layers (RDL); the dielectric layers are substantially coplanar with an upper surface of the substrate package; the core is located medially/laterally in the dielectric layers. In embodiment 200, a dielectric layer 208 with RDL conductive traces 206 is patterned and located on an upper surface of the core 202. Various embodiment may also have a dielectric layer 214 with RDL conductive traces 206 patterned and located on a lower surface of the core 202. The dielectric layers 208 and 214 can comprise a suitable nitride or oxide, such as silicon dioxide (SiO₂), carbon-doped silicon dioxide, fluorine-doped silicon dioxide, hydrogen-doped silicon dioxide, or silicon nitride. The dielectric layer 208 has vias or pillars 210, and the dielectric layer 214 has vias or pillars 216. Embodiment 200 illustrates the core 202 patterned with through-holes or through glass vias (TGVs) 204 that enable communication between RDL in dielectric layer 208 and RDL in dielectric layer 214. As illustrated in embodiment 250, the pillars or vias 210, 212, and 216, as well as the TGVs 204 are substantially perpendicular (i.e., 90 degrees plus or minus 18 degrees) to an upper surface 211 of the substrate package or core 202. In various embodiments, at 1104, a first conductive RDL layer is called seed 220. A location for an intended cavity is centrally depicted with a width 240.

The RDL/seed 220 may comprise a metal (e.g., copper, aluminum, nickel, cobalt, iron, tin, gold, silver, or combinations thereof) or another suitable conductive material. The seed 220 may have a thickness (measured in the Z direction in the figure) from about 1 micron to 10 microns. In various embodiments, the seed 220 may be substantially 5 microns. The RDL patterning may be performed using a modified semi-additive plating (MSAP) process, placing the seed 220.

A layer of resist 218 is overlaid on a portion of the seed 220 (at 1106), at the location that is designated to be a cavity to be later filled with an embedded organic bridge component, as is further developed with subsequent illustrations. A protective coating 222 may be overlaid on the resist 218 at 1106, followed by an etch that removes seed in locations that did not have the resist 218.

In the completed substrate package, the cavity portion of the dielectric comprises a smaller width, area, or volume, of an overall substrate under discussion. Accordingly, the width 240 is less than the width of the core 202 and package substrate. Additionally, the width 240 is a function of a width of a target organic embedded bridge component. The figures reflect cross-sectional views, in which the portion for the cavity is depicted as a width; however, in a top-down view, the portion for the cavity would appear as an area. In various embodiments, the width 240 may be from about 5 microns to about 40 microns in the X direction (or in the Y direction coming out of the page), along the upper surface 211.

At 1108, and with reference to FIG. 3, one or more additional dielectric layers 324 with RDL may be added to the upper surface surrounding the intended cavity area. Additionally, one or more dielectric layers 330 may be added to the lower surface of the embodiment 250. In the non-limiting example embodiment 300, dielectric layer 324 on the upper surface further includes two more layers of RDL conductive traces 328 and vias 326, and dielectric layer 330 on the lower surface further includes two more layers of RDL conductive traces 328 and vias 326. The dielectric layers 324 and 330 with RDL may be manufactured in accordance with conventional methodologies.

In various embodiments, the dielectric layer 324 and 330 can include, overlaid on the conductive trace material, a dielectric material, such as, a suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, a dielectric layer comprises a photo-imageable dielectric (PID). In some embodiments, the dielectric layer comprises an Ajinomoto Build-Up film (often referred to as ABF), which is a material that comprises an organic resin matrix with different types of fillers (for example, silica fillers of different sizes, or hollow fillers of different sizes) to control the coefficient of thermal expansion (CTE) and/or electrical properties (e.g., the dielectric constant (Dk), and/or dissipation factor (insertion loss) (Df)).

In some embodiments, it is advantageous for the dielectric layer (324, 330) to have a CTE that matches that of target dies (e.g., match the CTE of silicon in the IC die 102 or the die 106) attached to a substrate or PCB. In some embodiments, the dielectric material can have a CTE that is close (e.g., within 10%) to that of silicon. In other embodiments, the dielectric material can be any type of epoxy molding compound.

Also, at 1108, individual dielectric layers 324 and/or 330 may comprise multiple RDL conductive traces layered therein. In the example shown in FIG. 3, vertical conductive traces 326 and lateral traces 328 are located in dielectric layers 324 and 330, built up (in a Z direction in the figure) on a top surface or front side of the core 202, and on a back side of the core 202, respectively.

As with other RDL conductive traces described herein, the vias/vertical conductive traces 326 and lateral conductive traces 328 comprise electrically conductive material, such as, a metal (e.g., copper, aluminum, nickel, cobalt, iron, tin, gold, silver, or combinations thereof) or another suitable conductive material, and provide electrically conductive paths from an origin to a terminus of the respective trace. The dielectric layers 330 and 324 can be a suitable nitride or oxide, such as silicon dioxide (SiO₂), carbon-doped silicon dioxide, fluorine-doped silicon dioxide, hydrogen-doped silicon dioxide, or silicon nitride.

In other embodiments, there may be more or less layers of RDL in dielectric layers 324 and more or less layers of RDL in dielectric layers 330, and the number of RDL dielectric layers 324 does not necessarily match the number of RDL in dielectric layers 330.

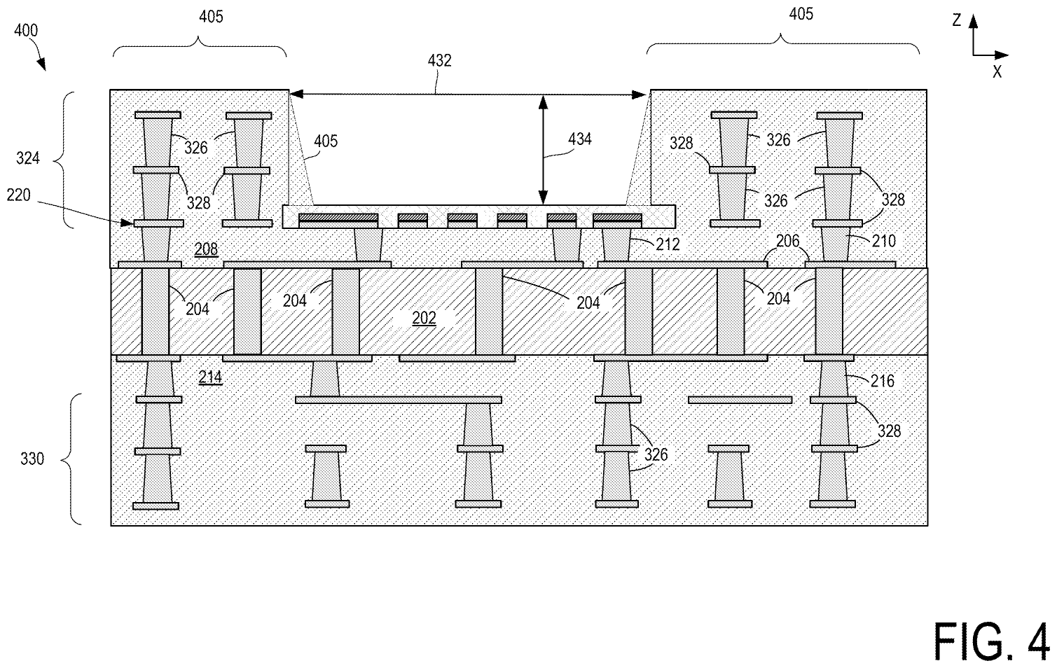

At 1110, the cavity is formed in the substrate. In various embodiments, this is achieved by removing dielectric material to expose the RDL over the seed 220 (embodiment 400). A laser ablation process or dry etch process may be used to remove the dielectric material and create the cavity located on the resist pattern 218. In other embodiments, the cavity is created in dielectric material or even in a layer of glass (“the core”) of the dielectric layer. Regardless of where the bottom of the cavity is located, the bottom of the cavity is (or has) the cavity floor; the cavity floor is where the embedded organic bridge component is to be placed and attached thereto. Although some of the figures illustrate the cavity as having perpendicular walls, this is to simplify drawings. In practice, the cavity walls 405 appear angled inward traveling from the upper surface to the cavity floor, as shown in FIG. 4.

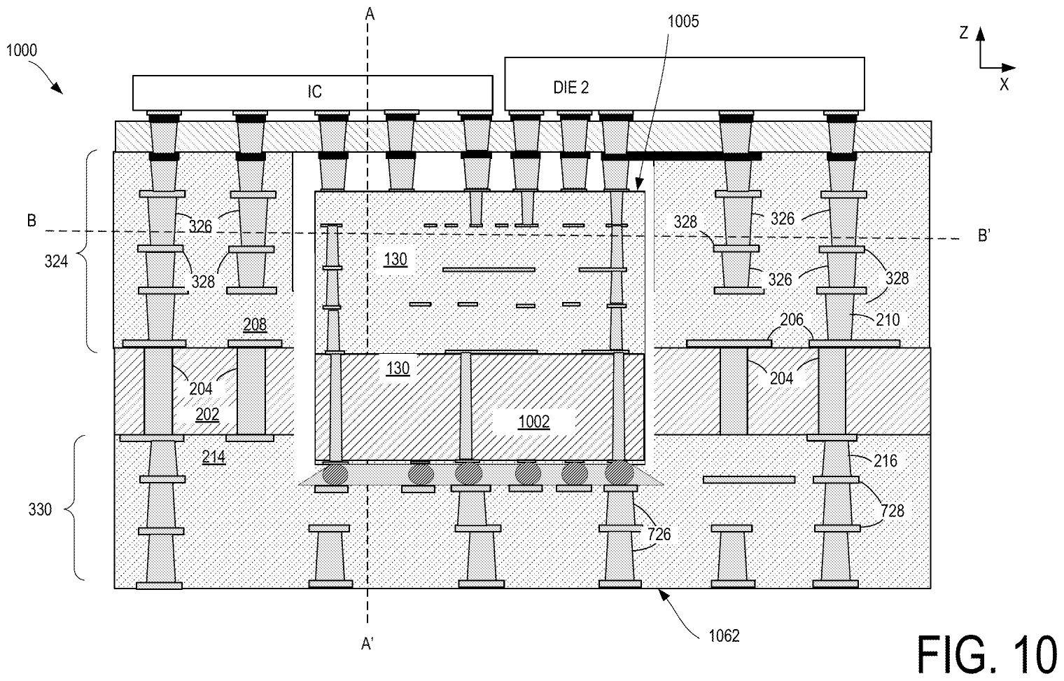

The cavity has a cavity depth 434 and a cavity width 432. The cavity depth 434 extends from an upper surface to a cavity floor and is a function of the thickness 140 of the embedded organic component that will be employed. As mentioned above, the embedded organic bridge component 120 thickness 140 can range from about 20% of the substrate package 112 thickness to about 70% of the substrate package 112 thickness, wherein about means plus or minus 10%. Referencing FIG. 10 cavity depth 1009, the cavity can have a cavity depth of 100 microns+/−10% to 1000 microns+/−10%, putting the cavity floor in a glass layer 1046 of the surrounding (core geometry RDL) dielectric, or even beneath a lower surface of the glass layer 1046 into the surrounding (core geometry RDL) dielectric (see, e.g., FIG. 11, embodiment 1100).

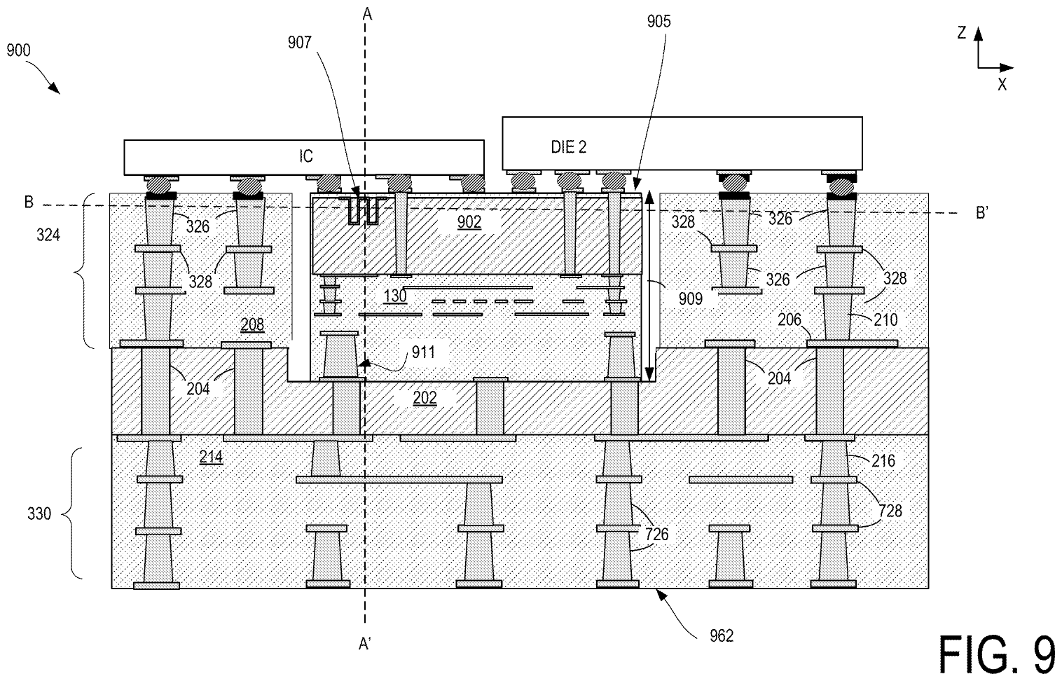

As those with skill in the art will appreciate, the cavity depth 434 maybe slightly larger than the embedded organic bridge component 120 thickness 140 to accommodate solder bumps and/or adhesive layers (e.g., a bond film) used to attach the embedded organic bridge component 120 to the substrate package 112 at the cavity floor. In some embodiments, the embedded organic bridge component 120 is hybrid bonded directly to RDL in the cavity floor (see, e.g., FIG. 9).

As mentioned above, the embedded organic bridge component thickness 140 can be more than half of the thickness of the substrate package (e.g., >50%). Further, in those embodiments, the cavity floor may be located in the core 202 or even below (in the figures) the core 202, extending into the dielectric/RDL layer 330.

Task 1102 represents manufacturing the embedded organic bridge component 120. In addition to manufacturing the embedded organic bridge component 120/705 to comprise the high-speed I/O and HD geometry, the embedded organic bridge component 120 can include other electrical components 142, such as trench capacitors 142. As may be appreciated, the tasks at 1104 to 1110 may be performed at the same manufacturing site as the tasks at 1102 and 1112, or at a geographically different location; further, tasks at 1102/1112 and 1104-1110 may be performed by different vendors.

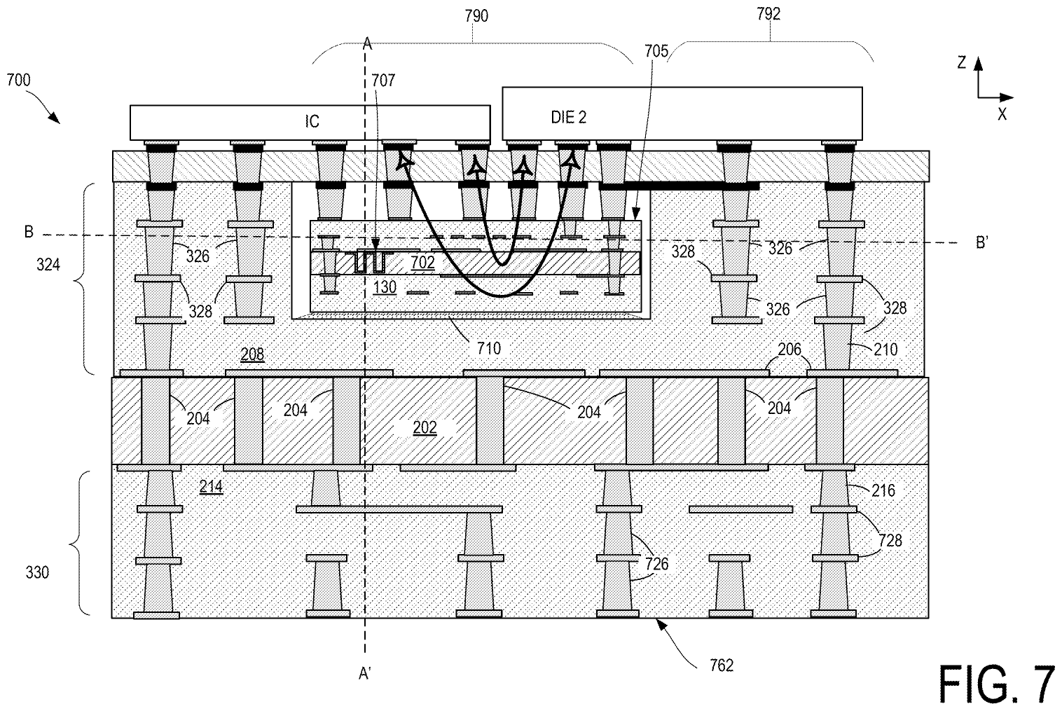

At 1114, the embedded organic bridge component 120 can be positioned in the cavity (embodiment 500) such that the solder bumps (when present) align with the RDL conductive contacts and traces/RDL in the cavity (embodiment 550). In other embodiments, when adhesive, bond films (e.g., bond film 710, FIG. 7), or hybrid bonding (FIG. 9) are employed, placement in the cavity proceeds accordingly. In various embodiments, underfill 546 may also be added between the embedded organic bridge component 120/705 and the cavity floor. As mentioned herein, after the embedded organic bridge component 120 is placed, the cavity around it is filled with dielectric material; this is left out on the figures to reduce the clutter of the images.

At 1114, the components in the embodiment may support operational communication with each other and may provide in a multi-die package the functionality conventionally associated with a monolithic system on chip (SoC). In various embodiments, at least one electrically communicative path from the first dielectric layer through a TGV to the second dielectric layer is a power route.

At 1116 the substrate package may be subjected to further patch fabrication, as illustrated in embodiment 700. For example, the upper surface 760 of the patch may planarized and more dielectric layers 780 with one or more RDL therein may be added to the upper surface. Further, overmolding and thermal solutions (not shown) may be added. Additionally, solder bumps may be added to the lower surface 762, etc. At 1218, additional die may be added, and optional mid-level interconnections may be added.

In various embodiments, the solder material for solder bumps 782 used to attach die IC 1 and die IC 2 has a lower melting point than solder used for solder bumps 138 on the embedded organic bridge component 120/705. In an embodiment, the solder material for solder bumps 782 may be a solder alloy such as tin and gold, or the like. In another embodiment, the solder material for solder bumps 138 could be tin and the solder material for solder bumps 782 could be a tin and gold compound. This increases the reliability of the solder attach of the embedded component (and by extension, any product that includes the embodiment) by preventing the embedded component to loosen or move around when heat is applied to attach die at the upper surface. Also, at 1218, the components in the embodiment may support operational communication with each other.

Upon review, and comparing FIG. 1 to FIG. 6, the upper surface of a substrate package will have a first arrangement 692 of first conductive contacts at a first pitch (“core pitch”) and a second arrangement 690 of second conductive contacts at a second pitch (“bridge pitch,” or the herein described HD pitch/geometry). The lower surface 662 of the substrate package has a third arrangement of third conductive contacts at a third pitch, which may be a ball grid array BGA or LGA pitch. In various embodiments, the second pitch is less than three microns+/−20% and the first pitch and the third pitch are greater than 8 microns+/−20%. There is a layer of dielectric material between the upper surface and the lower surface, and the layer of dielectric material comprises a first region dielectric layer 324 and a second region 130 (the organic embedded bridge component). As described above, the first region dielectric layer 324 includes first redistribution layers (RDL) with a width of greater than 9 microns+/−20% (convention or core geometry, a 9/12 geometry). The second region 130 includes second redistribution layers (RDL) with a width of less than three microns+/−20% (the HD geometry, a 3/3 or less geometry). The first region and the second region abut each other substantially perpendicular to the upper surface. Also, we see that the first RDL provides an electrical path between a first of the first conductive contacts and a first of the third conductive contacts; the second RDL provides an electrical path 794 between a first of the second conductive contacts and a second of the second conductive contacts; and in various embodiments, the second RDL further provides an electrical path 796 between a third of the second conductive contacts and a second of the third conductive contacts. Large arrows are used to show some of these paths.

In FIG. 7, a couple of variations are illustrated using embodiment 700. The features illustrated in embodiment 700 need not be implemented together; they can be mixed and matched with other features in FIG. 6, FIG. 6, FIG. 9., and FIG. 10. As a first variation, the resist pattern 218 is omitted and the embedded organic bridge component 705 (second dielectric region) may be attached directly to the cavity floor with a bond film 710, as illustrated. In various embodiments, the bond film 710 can be anisotropic bond film to permit conductive paths in the vertical or Z direction. In another variation, the embedded organic component 705 has a core 702. The core 702 can comprise glass or an epoxy, as described herein, and further, may be manufactured to have through glass vias (TGVs) with the smaller, HDL geometry, in this illustration, and dielectric layers/RDL patterned on an upper surface and lower surface, also as described herein. In yet another variation, the embedded organic component 705 has one or more trench capacitors 707 in the glass core 702, comprising an ONO layer and a polysilicon layer, also as described above.

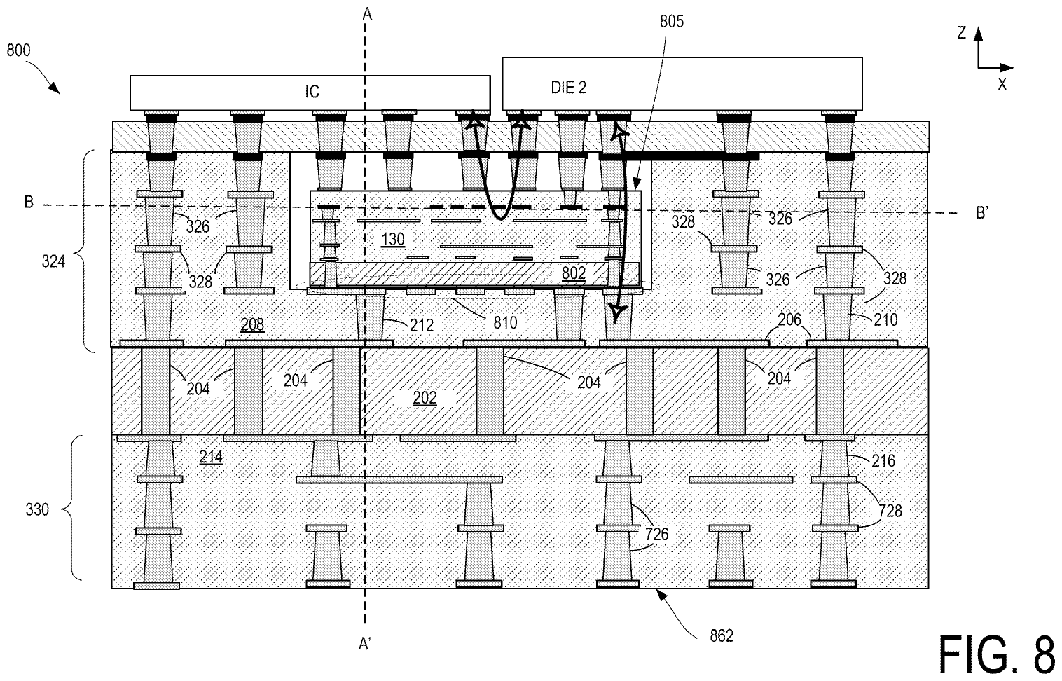

In FIG. 8, the embedded organic bridge component 805 is hybrid bonded in the cavity, to the cavity floor. The hybrid bonding can be detected by finding at the cavity floor 810, copper to copper (Cu—Cu) fused interconnects and dielectric fused to dielectric. Another feature illustrated in FIG. 8 is the location of the glass layer 802. Embodiments of the organic bridge component 805 that are configured with the glass layer 802 at bottom improve hybrid bonding by providing a flat, planar lower surface of the organic bridge component 805. The cavity around the organic bridge component 805 may be filled with a dielectric (omitted from the image to avoid cluttering the image). One or more layers of RDL/dielectric may be layered over the top of the embedded organic bridge component 805, as shown.

In FIG. 9, an embodiment 900 depicts the organic bridge component 905 with the glass layer 902 located near or at the upper surface, in an open cavity configuration. The IC and the die 2 are solder attached to the upper surface of the substrate package and to the upper surface of the organic bridge component 905, with no intervening RDL/dielectric material. This configuration of the organic bridge component 905 is favorable for open cavity die attach embodiments because it can enhance the upper surface planarity and, based thereon, reduce bump thickness variation (BTV) on the upper surface. As shown, a trench capacitor 907 in the glass layer 902 can be easier to manufacture when the glass layer 902 is at the surface, as shown.

Another feature depicted in embodiment 900 is the organic bridge component 905 having a thickness 909 such that it extends into the core 202 of the substrate package. In these embodiments, a lower layer of RDL comprises vias 911 and contacts that have the larger core geometry (e.g., 9/12, described above); this enables the lower surface of the organic bridge component 905 to be attached to vias in the core 202.

FIG. 10 is an embodiment 1000 that depicts the organic bridge component 1005 with the glass layer 1002 located near the bottom again. In this embodiment, the organic bridge component 1005 has a thickness such that it extends through the core 202 of the substrate package and into the lower dielectric layer 330 on the bottom side of the core 202, or bottom side of the substrate package. In a fabrication process, a cavity is created within the substrate package that has a cavity floor in the lower dielectric layer 330, therefore, the cavity includes an opening in the core 202. In these embodiments, the organic bridge component 1005 can comprise multiple layers of RDL with the HD geometry; there is no need to translate the HD geometry (3/3 or less) to the core geometry in the body of the organic bridge component 1005 when it is attached to a cavity floor in lower dielectric layer 330. As before, there are various ways the organic bridge component 1005 can be attached to the cavity floor, such as, with hybrid fusion and with solder attach and underfill.

Thus, various non-limiting embodiments of an embedded organic bridge component for a semiconductor package have been described. Embodiments can exhibit distinct features in SEM/TEM images, such as, a transition of the width/spacing of traces or RDL from conventional core (9/12) geometry to high density (HD) (3/3 or less) geometry in a designated region. For example, dashed lines A-A′ or B-B′ in FIG. 7 and dashed lines A-A′ or B-B′ in FIG. 7 illustrate some potential views through a Z-X plane which these transitions in width and spacing could be viewed. Similar potential views could be achieved in an X-Y plane. Further, in various assembly and device embodiments, extra die and/or components may be present. The following description provides additional details and context for various die and various package assembly and device configurations that can be created based on or using the provided embodiments.

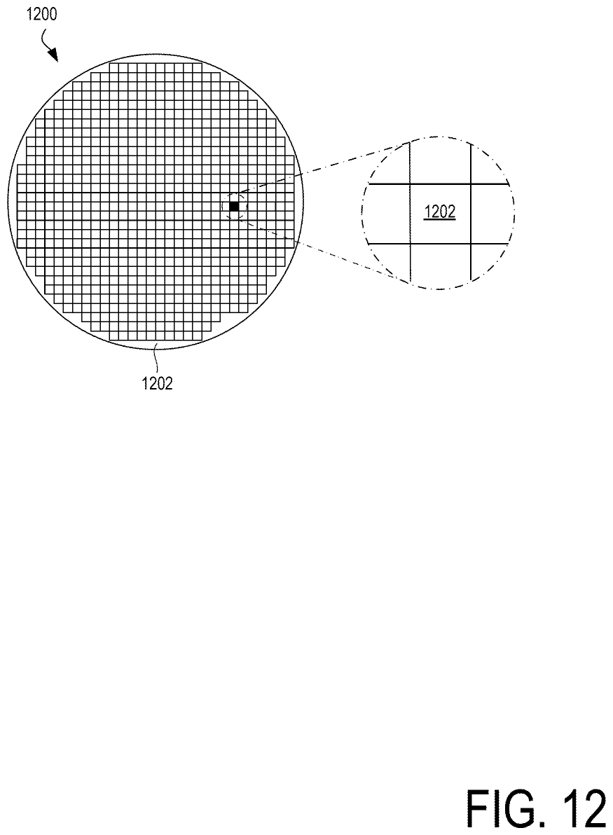

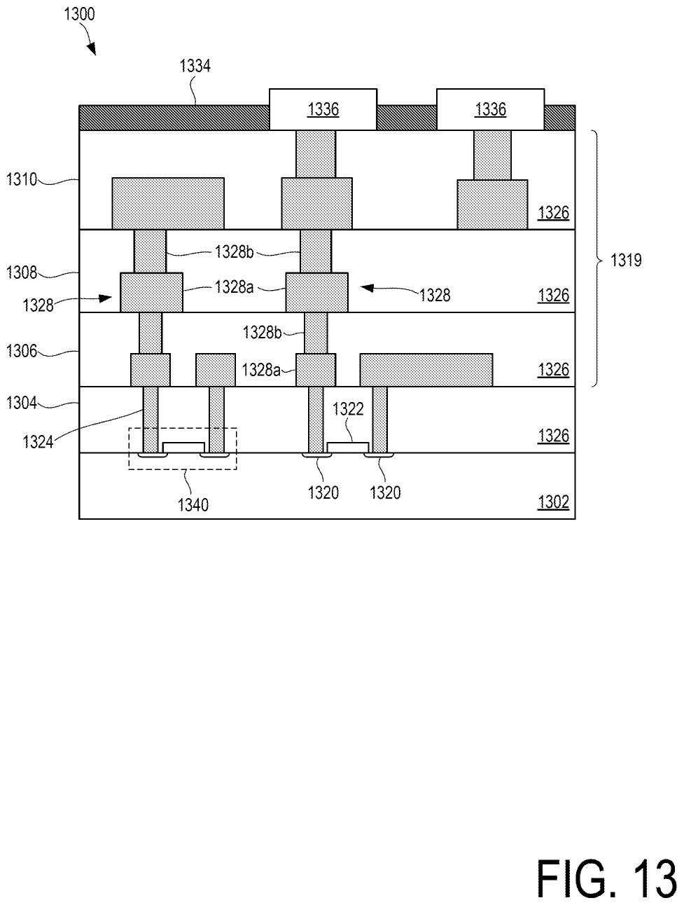

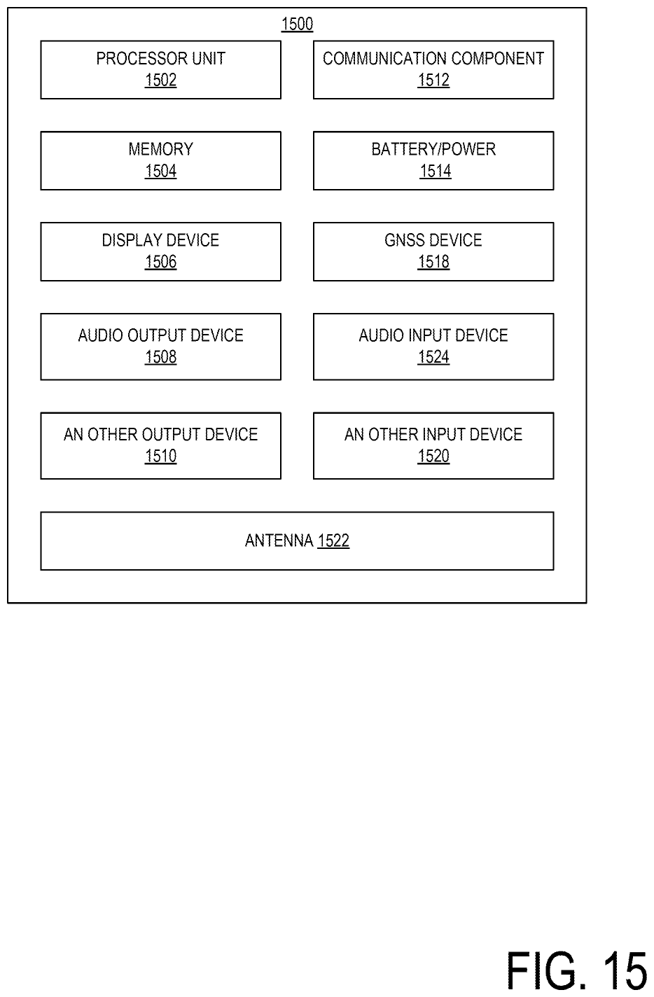

FIG. 12 is a top view of a wafer 1200 and dies 1202 that may be included in any of the embodiments disclosed herein. The wafer 1200 may be composed of semiconductor material and may include one or more dies 1202 formed on a surface of the wafer 1200. After the fabrication of the integrated circuit components on the wafer 1200 is complete, the wafer 1200 may undergo a singulation process in which the dies 1202 are separated from one another to provide discrete “chips” or destined for a packaged integrated circuit component. The individual dies 1202, comprising an integrated circuit component, may include one or more transistors (e.g., some of the transistors 1340 of FIG. 13, discussed below), supporting circuitry to route electrical signals to the transistors, passive components (e.g., signal traces, resistors, capacitors, or inductors), and/or any other integrated circuit components. In some embodiments, the wafer 1200 or the die 1202 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 1202. For example, a memory array formed by multiple memory devices may be formed on a same die 1202 as a processor unit (e.g., the processor unit 1502 of FIG. 15) or other logic that is configured to store information in the memory devices or execute instructions stored in the memory array. In some embodiments, a die 1202 may be attached to a wafer 1200 that includes other die, and the wafer 1200 is subsequently singulated, this manufacturing procedure is referred to as a die-to-wafer assembly technique.

FIG. 13 is a cross-sectional side view of an integrated circuit 1300 that may be included in any of the embodiments disclosed herein. One or more of the integrated circuits 1300 may be included in one or more dies 1202 (FIG. 12). The integrated circuit 1300 may be formed on a die substrate 1302 (e.g., the wafer 1200 of FIG. 12) and may be included in a die (e.g., the die 1202 of FIG. 12).

The die substrate 1302 may be a semiconductor substrate composed of semiconductor material systems including, for example, n-type or p-type materials systems (or a combination of both). The die substrate 1302 may include, for example, a crystalline substrate formed using a bulk silicon or a silicon-on-insulator (SOI) substructure. In some embodiments, the die substrate 1302 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1302. Although a few examples of materials from which the die substrate 1302 may be formed are described here, any material that may serve as a foundation for an integrated circuit 1300 may be used. The die substrate 1302 may be part of a singulated die (e.g., the dies 1202 of FIG. 12) or a wafer (e.g., the wafer 1200 of FIG. 12).

The integrated circuit 1300 may include one or more device layers 1304 disposed on the die substrate 1302. The device layer 1304 may include features of one or more transistors 1340 (e.g., metal oxide semiconductor field-effect transistors (MOSFETs)) formed on the die substrate 1302. The transistors 1340 may include, for example, one or more source and/or drain (S/D) regions 1320, a gate 1322 to control current flow between the S/D regions 1320, and one or more S/D contacts 1324 to route electrical signals to/from the S/D regions 1320.

The gate 1322 may be formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 1340 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1340 along the source-channel-drain direction, the gate electrode may comprise a U-shaped structure that includes a bottom portion substantially parallel to the surface of the die substrate 1302 and two sidewall portions that are substantially perpendicular to the top surface of the die substrate 1302. In other embodiments, at least one of the metal layers that form the gate electrode may simply be a planar layer that is substantially parallel to the top surface of the die substrate 1302 and does not include sidewall portions substantially perpendicular to the top surface of the die substrate 1302. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching processes. In some embodiments, a plurality of spacer pairs may be used; for instance, two pairs, three pairs, or four pairs of sidewall spacers may be formed on opposing sides of the gate stack.

The S/D regions 1320 may be formed within the die substrate 1302 adjacent to the gate 1322 of individual transistors 1340. The S/D regions 1320 may be formed using an implantation/diffusion process or an etching/deposition process, for example. In the former process, dopants such as boron, aluminum, antimony, phosphorous, or arsenic may be ion-implanted into the die substrate 1302 to form the S/D regions 1320. An annealing process that activates the dopants and causes them to diffuse farther into the die substrate 1302 may follow the ion-implantation process. In the latter process, the die substrate 1302 may first be etched to form recesses at the locations of the S/D regions 1320. An epitaxial deposition process may then be conducted to fill the recesses with material that is used to fabricate the S/D regions 1320. In some implementations, the S/D regions 1320 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1320 may be formed using one or more alternate semiconductor materials such as germanium or a group III-V material or alloy. In further embodiments, one or more layers of metal and/or metal alloys may be used to form the S/D regions 1320.

Electrical signals, such as power and/or input/output (I/O) signals, may be routed to and/or from the devices (e.g., transistors 1340) of the device layer 1304 through one or more interconnect layers disposed on the device layer 1304 (illustrated in FIG. 13 as interconnect layers 1306-1310). For example, electrically conductive features of the device layer 1304 (e.g., the gate 1322 and the S/D contacts 1324) may be electrically coupled with the interconnect structures 1328 of the interconnect layers 1306-1310. The one or more interconnect layers 1306-1310 may form a metallization stack (also referred to as an “ILD stack”) 1319 of the integrated circuit 1300.

The interconnect structures 1328 may be arranged within the interconnect layers 1306-1310 to route electrical signals according to a wide variety of designs; in particular, the arrangement is not limited to the particular configuration of interconnect structures 1328 depicted in FIG. 13. Although a particular number of interconnect layers 1306-1310 is depicted in FIG. 13, embodiments of the present disclosure include integrated circuits having more or fewer interconnect layers than depicted.

In some embodiments, the interconnect structures 1328 may include lines 1328a and/or vias 1328b filled with an electrically conductive material such as a metal. The lines 1328a may be arranged to route electrical signals in a direction of a plane that is substantially parallel with a surface of the die substrate 1302 upon which the device layer 1304 is formed. For example, the lines 1328a may route electrical signals in a direction in and out of the page and/or in a direction across the page. The vias 1328b may be arranged to route electrical signals in a direction of a plane that is substantially perpendicular to the surface of the die substrate 1302 upon which the device layer 1304 is formed. In some embodiments, the vias 1328b may electrically couple lines 1328a of different interconnect layers 1306-1310 together.

The interconnect layers 1306-1310 may include a dielectric material 1326 disposed between the interconnect structures 1328, as shown in FIG. 13. In some embodiments, dielectric material 1326 disposed between the interconnect structures 1328 in different ones of the interconnect layers 1306-1310 may have different compositions; in other embodiments, the composition of the dielectric material 1326 between different interconnect layers 1306-1310 may be the same. The device layer 1304 may include a dielectric material 1326 disposed between the transistors 1340 and a bottom layer of the metallization stack as well. The dielectric material 1326 included in the device layer 1304 may have a different composition than the dielectric material 1326 included in the interconnect layers 1306-1310; in other embodiments, the composition of the dielectric material 1326 in the device layer 1304 may be the same as a dielectric material 1326 included in any one of the interconnect layers 1306-1310.

A first interconnect layer 1306 (referred to as Metal 1 or “M1”) may be formed directly on the device layer 1304. In some embodiments, the first interconnect layer 1306 may include lines 1328a and/or vias 1328b, as shown. The lines 1328a of the first interconnect layer 1306 may be coupled with contacts (e.g., the S/D contacts 1324) of the device layer 1304. The vias 1328b of the first interconnect layer 1306 may be coupled with the lines 1328a of a second interconnect layer 1308.

The second interconnect layer 1308 (referred to as Metal 2 or “M2”) may be formed directly on the first interconnect layer 1306. In some embodiments, the second interconnect layer 1308 may include via 1328b to couple the lines 1328 of the second interconnect layer 1308 with the lines 1328a of a third interconnect layer 1310. Although the lines 1328a and the vias 1328b are structurally delineated with a line within individual interconnect layers for the sake of clarity, the lines 1328a and the vias 1328b may be structurally and/or materially contiguous (e.g., simultaneously filled during a dual-damascene process) in some embodiments.

The third interconnect layer 1310 (referred to as Metal 3 or “M3”) (and additional interconnect layers, as desired) may be formed in succession on the second interconnect layer 1308 according to similar techniques and configurations described in connection with the second interconnect layer 1308 or the first interconnect layer 1306. In some embodiments, the interconnect layers that are “higher up” in the metallization stack 1319 in the integrated circuit 1300 (i.e., farther away from the device layer 1304) may be thicker that the interconnect layers that are lower in the metallization stack 1319, with lines 1328a and vias 1328b in the higher interconnect layers being thicker than those in the lower interconnect layers.

The integrated circuit 1300 may include a solder resist material 1334 (e.g., polyimide or similar material) and one or more conductive contacts 1336 formed on the interconnect layers 1306-1310. In FIG. 13, the conductive contacts 1336 are illustrated as taking the form of bond pads. The conductive contacts 1336 may be electrically coupled with the interconnect structures 1328 and configured to route the electrical signals of the transistor(s) 1340 to external devices. For example, solder bonds may be formed on the one or more conductive contacts 1336 to mechanically and/or electrically couple an integrated circuit die including the integrated circuit 1300 with another component (e.g., a printed circuit board). The integrated circuit 1300 may include additional or alternate structures to route the electrical signals from the interconnect layers 1306-1310; for example, the conductive contacts 1336 may include other analogous features (e.g., posts) that route the electrical signals to external components.

In some embodiments in which the integrated circuit 1300 is a double-sided die, the integrated circuit 1300 may include another metallization stack (not shown) on the opposite side of the device layer(s) 1304. This metallization stack may include multiple interconnect layers as discussed above with reference to the interconnect layers 1306-1310, to provide electrically conductive paths (e.g., including conductive lines and vias) between the device layer(s) 1304 and additional conductive contacts (not shown) on the opposite side of the integrated circuit 1300 from the conductive contacts 1336.

In other embodiments in which the integrated circuit 1300 is a double-sided die, the integrated circuit 1300 may include one or more through-silicon vias (TSVs) through the die substrate 1302; these TSVs may make contact with the device layer(s) 1304, and may provide electrically conductive paths between the device layer(s) 1304 and additional conductive contacts (not shown) on the opposite side of the integrated circuit 1300 from the conductive contacts 1336. In some embodiments, TSVs extending through the substrate can be used for routing power and ground signals from conductive contacts on the opposite side of the integrated circuit 1300 from the conductive contacts 1336 to the transistors 1340 and any other components integrated into the die 1300, and the metallization stack 1319 can be used to route I/O signals from the conductive contacts 1336 to transistors 1340 and any other components integrated into the die 1300.

Multiple integrated circuits 1300 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

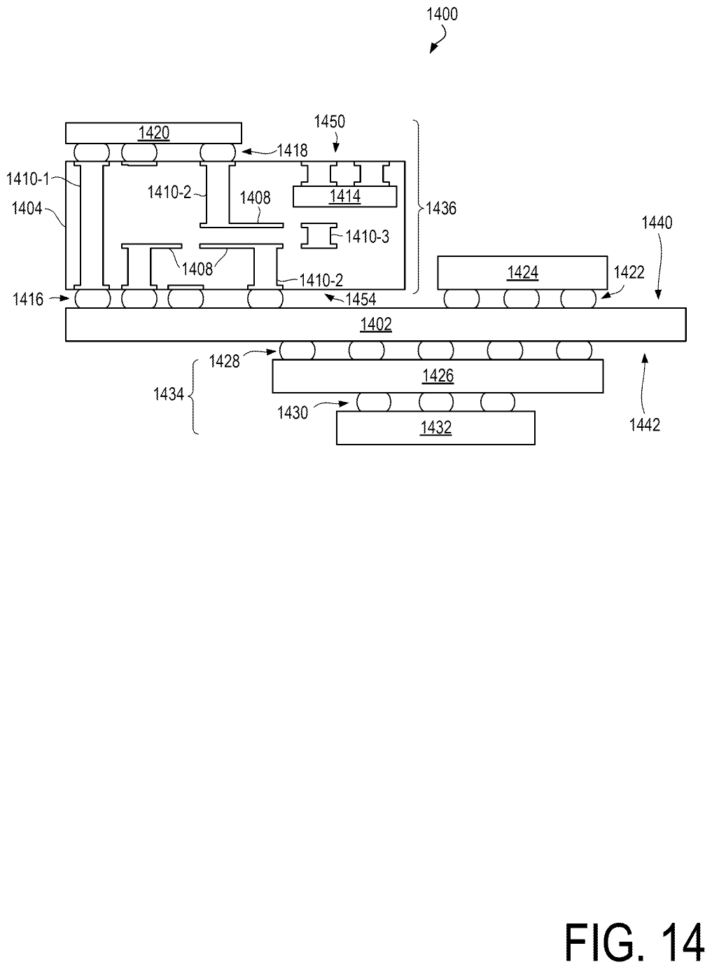

FIG. 14 is a cross-sectional side view of a microelectronic assembly 1400 that may include any of the embodiments disclosed herein. The microelectronic assembly 1400 includes multiple integrated circuit components disposed on a circuit board 1402 (which may be a motherboard, system board, mainboard, etc.). The microelectronic assembly 1400 may include components disposed on a first face 1440 of the circuit board 1402 and an opposing second face 1442 of the circuit board 1402; generally, components may be disposed on one or both faces 1440 and 1442.

In some embodiments, the circuit board 1402 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1402. In other embodiments, the circuit board 1402 may be a non-PCB substrate. The microelectronic assembly 1400 illustrated in FIG. 14 includes a package-on-interposer structure 1436 coupled to the first face 1440 of the circuit board 1402 by coupling components 1416. The coupling components 1416 may electrically and mechanically couple the package-on-interposer structure 1436 to the circuit board 1402, and may include solder balls (as shown in FIG. 14), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1436 may include an integrated circuit component 1420 coupled to an interposer 1404 by coupling components 1418. The coupling components 1418 may take any suitable form for the application, such as the forms discussed above with reference to the coupling components 1416. Although a single integrated circuit component 1420 is shown in FIG. 14, multiple integrated circuit components may be coupled to the interposer 1404; indeed, additional interposers may be coupled to the interposer 1404. The interposer 1404 may provide an intervening substrate used to bridge the circuit board 1402 and the integrated circuit component 1420.

The integrated circuit component 1420 may be a packaged or unpackaged integrated circuit component that includes one or more integrated circuit dies (e.g., the die 1202 of FIG. 12, the integrated circuit 1300 of FIG. 13) and/or one or more other suitable components.

The unpackaged integrated circuit component 1420 comprises solder bumps attached to contacts on the die. The solder bumps allow the die to be directly attached to the interposer 1404. In embodiments where the integrated circuit component 1420 comprises multiple integrated circuit die, the dies can be of the same type (a homogeneous multi-die integrated circuit component) or of two or more different types (a heterogeneous multi-die integrated circuit component). In addition to comprising one or more processor units, the integrated circuit component 1420 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1404 may spread connections to a wider pitch or reroute a connection to a different connection. For example, the interposer 1404 may couple the integrated circuit component 1420 to a set of ball grid array (BGA) conductive contacts of the coupling components 1416 for coupling to the circuit board 1402. In the embodiment illustrated in FIG. 14, the integrated circuit component 1420 and the circuit board 1402 are attached to opposing sides of the interposer 1404; in other embodiments, the integrated circuit component 1420 and the circuit board 1402 may be attached to a same side of the interposer 1404. In some embodiments, three or more components may be interconnected by way of the interposer 1404.

In some embodiments, the interposer 1404 may be formed as a PCB, including multiple metal layers separated from one another by layers of dielectric material and interconnected by electrically conductive vias. In some embodiments, the interposer 1404 may be formed of an epoxy resin, a fiberglass-reinforced epoxy resin, an epoxy resin with inorganic fillers, a ceramic material, or a polymer material such as polyimide. In some embodiments, the interposer 1404 may be formed of alternate rigid or flexible materials that may include the same materials described above for use in a semiconductor substrate, such as silicon, germanium, and other group III-V and group IV materials. The interposer 1404 may include metal interconnects 1408 and vias 1410, including but not limited to through hole vias 1410-1 (that extend from a first face 1450 of the interposer 1404 to a second face 1454 of the interposer 1404), blind vias 1410-2 (that extend from the first or second faces 1450 or 1454 of the interposer 1404 to an internal metal layer), and buried vias 1410-3 (that connect internal metal layers).

In some embodiments, the interposer 1404 can comprise a silicon interposer. Through-silicon vias (TSV) extending through the silicon interposer can connect connections on the first face of a silicon interposer to an opposing second face of the silicon interposer. In some embodiments, an interposer 1404 comprising a silicon interposer can further comprise one or more routing layers to route connections on a first face of the interposer 1404 to an opposing second face of the interposer 1404.

The interposer 1404 may further include embedded devices 1414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1404. The package-on-interposer structure 1436 may take the form of any of the package-on-interposer structures known in the art.

The integrated circuit assembly 1400 may include an integrated circuit component 1424 coupled to the first face 1440 of the circuit board 1402 by coupling components 1422. The coupling components 1422 may take the form of any of the embodiments discussed above with reference to the coupling components 1416, and the integrated circuit component 1424 may take the form of any of the embodiments discussed above with reference to the integrated circuit component 1420.

The integrated circuit assembly 1400 illustrated in FIG. 14 includes a package-on-package structure 1434 coupled to the second face 1442 of the circuit board 1402 by coupling components 1428. The package-on-package structure 1434 may include an integrated circuit component 1426 and an integrated circuit component 1432 coupled together by coupling components 1430 such that the integrated circuit component 1426 is disposed between the circuit board 1402 and the integrated circuit component 1432. The coupling components 1428 and 1430 may take the form of any of the embodiments of the coupling components 1416 discussed above, and the integrated circuit components 1426 and 1432 may take the form of any of the embodiments of the integrated circuit component 1420 discussed above. The package-on-package structure 1434 may be configured in accordance with any of the package-on-package structures known in the art.

FIG. 15 is a block diagram of an example electrical device 1500 that may include one or more of the embodiments disclosed herein. For example, any suitable ones of the components of the electrical device 1500 may include one or more of the microelectronic assemblies 1400, integrated circuit components 1420, integrated circuits 1300, integrated circuit dies 1202, or structures disclosed herein. A number of components are illustrated in FIG. 15 as included in the electrical device 1500, but any one or more of these components may be omitted or duplicated, as suitable for the application. In some embodiments, some or all the components included in the electrical device 1500 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 1500 may not include one or more of the components illustrated in FIG. 15, but the electrical device 1500 may include interface circuitry for coupling to the one or more components. For example, the electrical device 1500 may not include a display device 1506, but may include display device interface circuitry (e.g., a connector and driver circuitry) to which a display device 1506 may be coupled. In another set of examples, the electrical device 1500 may not include an audio input device 1524 or an audio output device 1508, but may include audio input or output device interface circuitry (e.g., connectors and supporting circuitry) to which an audio input device 1524 or audio output device 1508 may be coupled.

The electrical device 1500 may include one or more processor units 1502 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1502 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1500 may include a memory 1504, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1504 may include memory that is located on the same integrated circuit die as the processor unit 1502. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1500 can comprise one or more processor units 1502 that are heterogeneous or asymmetric to another processor unit 1502 in the electrical device 1500. There can be a variety of differences between the processor units 1502 in a system in terms of a spectrum of metrics of merit including architectural, microarchitectural, thermal, power consumption characteristics, and the like. These differences can effectively manifest themselves as asymmetry and heterogeneity among the processor units 1502 in the electrical device 1500.

In some embodiments, the electrical device 1500 may include a communication component 1512 (e.g., one or more communication components). For example, the communication component 1512 can manage wireless communications for the transfer of data to and from the electrical device 1500. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1512 may operate in accordance with other wireless protocols in other embodiments. The electrical device 1500 may include an antenna 1522 to facilitate wireless communications and/or to receive other wireless communications (such as AM or FM radio transmissions).

In some embodiments, the communication component 1512 may manage wired communications, such as electrical, optical, or any other suitable communication protocols (e.g., IEEE 802.3 Ethernet standards). As noted above, the communication component 1512 may include multiple communication components. For instance, a first communication component 1512 may be dedicated to shorter-range wireless communications such as Wi-Fi or Bluetooth, and a second communication component 1512 may be dedicated to longer-range wireless communications such as global positioning system (GPS), EDGE, GPRS, CDMA, WiMAX, LTE, EV-DO, or others. In some embodiments, a first communication component 1512 may be dedicated to wireless communications, and a second communication component 1512 may be dedicated to wired communications.

The electrical device 1500 may include battery/power circuitry 1514. The battery/power circuitry 1514 may include one or more energy storage devices (e.g., batteries or capacitors) and/or circuitry for coupling components of the electrical device 1500 to an energy source separate from the electrical device 1500 (e.g., AC line power).

The electrical device 1500 may include a display device 1506 (or corresponding interface circuitry, as discussed above). The display device 1506 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1500 may include an audio output device 1508 (or corresponding interface circuitry, as discussed above). The audio output device 1508 may include any embedded or wired or wirelessly connected external device that generates an audible indicator, such speakers, headsets, or earbuds.

The electrical device 1500 may include an audio input device 1524 (or corresponding interface circuitry, as discussed above). The audio input device 1524 may include any embedded or wired or wirelessly connected device that generates a signal representative of a sound, such as microphones, microphone arrays, or digital instruments (e.g., instruments having a musical instrument digital interface (MIDI) output). The electrical device 1500 may include a Global Navigation Satellite System (GNSS) device 1518 (or corresponding interface circuitry, as discussed above), such as a Global Positioning System (GPS) device. The GNSS device 1518 may be in communication with a satellite-based system and may determine a geolocation of the electrical device 1500 based on information received from one or more GNSS satellites, as known in the art.

The electrical device 1500 may include another output device 1510 (or corresponding interface circuitry, as discussed above). Examples of the other output device 1510 may include an audio codec, a video codec, a printer, a wired or wireless transmitter for providing information to other devices, or an additional storage device.

The electrical device 1500 may include another input device 1520 (or corresponding interface circuitry, as discussed above). Examples of the other input device 1520 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1500 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1500 may be any other electronic device that processes data. In some embodiments, the electrical device 1500 may comprise multiple discrete physical components. Given the range of devices that the electrical device 1500 can be manifested as in various embodiments, in some embodiments, the electrical device 1500 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Unless otherwise stated, terms or values modified by the word “substantially” include arrangements, orientations, spacings, or positions that vary plus or minus 20% from the meaning of the unmodified term or value. Terms or values modified by the word “about” include values inclusive of 10% less than the term or value to inclusive of 10% greater than the term or value.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

The following examples pertain to additional embodiments of technologies disclosed herein.

### Examples

Example 1 is a substrate package comprising: an upper surface comprising a first arrangement of first conductive contacts at a first pitch and a second arrangement of second conductive contacts at a second pitch; a lower surface comprising a third arrangement of third conductive contacts at a third pitch; wherein the second pitch is less than three microns+/−20% and the first pitch and the third pitch are greater than 8 microns+/−20%; a first region of a first dielectric material between the upper surface and the lower surface; a second region of a second dielectric material between the upper surface and the lower surface; wherein the first region and second region abut one another substantially perpendicular to the upper surface; wherein the first region includes first redistribution layers (RDL) with a width of greater than 9 microns+/−20%; wherein the second region includes second redistribution layers (RDL) with a width of less than three microns+/−20%; wherein the first RDL provides an electrical path between a first of the first conductive contacts and a first of the third conductive contacts; and wherein the second RDL provides an electrical path between a first of the second conductive contacts and a second of the second conductive contacts.

Example 2 includes the subject matter of Example 1, wherein the second RDL further provides at least part of an electrical path between a third of the second conductive contacts and a second of the third conductive contacts.

Example 3 includes the subject matter of Example 1, wherein the first dielectric material and the second dielectric material are the same.

Example 4 includes the subject matter of Example 1, wherein the first dielectric material and the second dielectric material are different.

Example 5 includes the subject matter of any one of Examples 1-4, further comprising a first lateral layer of glass with through glass vias (TGVs) in the first region.

Example 6 includes the subject matter of Example 5, wherein the first lateral layer of glass has a thickness in a range of 100 microns+/−10% to 1.5 millimeters+/−10%.

Example 7 includes the subject matter of Example 5, wherein the first lateral layer of glass extends underneath the second region, and further comprising: a cavity floor formed in the first lateral layer of glass underneath the second region; and wherein the second RDL in the second region is operationally coupled to some of the TGVs in the cavity floor.

Example 8 includes the subject matter of any one of Examples 1-4, further comprising a lateral layer of epoxy in the first RDL.

Example 9 includes the subject matter of Example 1, wherein the first RDL and the second RDL comprise copper.

Example 10 includes the subject matter of Example 5 or Example 7, further comprising a second layer of glass with through glass vias in the second region.

Example 11 includes the subject matter of any one of Examples 1-10, further comprising: a portion of the first region that extends underneath the second region; and a cavity with a cavity floor formed below the second region in the portion of the first region.

Example 12 includes the subject matter of Example 11, wherein the second region is attached via a bond film in the cavity floor.

Example 13 includes the subject matter of Example 11, wherein the second region is attached via hybrid bonding or solder bumps in the cavity floor.

Example 14 includes the subject matter of Example 13, wherein the second RDL is operationally coupled to the first RDL in the cavity floor.

Example 15 includes the subject matter of Example 11, wherein the second RDL is operationally coupled to the third arrangement of conductive contacts via the portion of the first region.

Example 16 includes the subject matter of any one of Examples 1-15, further comprising: a layer of a third dielectric material between the lower surface and the first region and the second region.

Example 17 includes the subject matter of any one of Examples 1-16, further comprising: a first integrated circuit die attached to the first conductive contacts and a first portion of the second conductive contacts; and a second integrated circuit die attached to a second portion of the second conductive contacts.

Example 18 is a package assembly comprising the substrate package of any one of Examples 1-17, further comprising: a first integrated circuit die attached to the first conductive contacts and a first portion of the second conductive contacts; and a second integrated circuit die attached to a second portion of the second conductive contacts; and solder balls attached to the third conductive contacts.

Example 19 includes the subject matter of Example 18, further comprising a printed circuit board (PCB), the PCB attached to the solder balls.

Example 20 is a method, comprising: fabricating a substrate package having a layer of dielectric material between and upper surface and a lower surface, wherein the dielectric material has therein first redistribution layers (RDL) at a pitch greater than 9 microns+/−20%, and wherein the upper surface comprises a first arrangement of first conductive contacts at a first pitch and a second arrangement of second conductive contacts at a second pitch; creating a cavity with a cavity floor in the dielectric material; fabricating an organic bridge component having second RDL at a pitch of three microns+/−10% or less; and attaching the organic bridge component to the cavity floor to thereby create electrical paths between individuals of the second conductive contacts at the upper surface.

What is claimed is:

1. A substrate package comprising:
an upper surface comprising a first arrangement of first conductive contacts at a first pitch and a second arrangement of second conductive contacts at a second pitch;
a lower surface comprising a third arrangement of third conductive contacts at a third pitch;
wherein the second pitch is less than three microns+/−20% and the first pitch and the third pitch are greater than 8 microns+/−20%;
a first region of a first dielectric material between the upper surface and the lower surface;
a second region of a second dielectric material between the upper surface and the lower surface;
wherein the first region and second region abut one another substantially perpendicular to the upper surface;
wherein the first region includes first redistribution layers (RDL) with a width of greater than 9 microns+/−20%;
wherein the second region includes second redistribution layers (RDL) with a width of less than three microns+/−20%;
wherein the first RDL provides an electrical path between a first of the first conductive contacts and a first of the third conductive contacts; and
wherein the second RDL provides an electrical path between a first of the second conductive contacts and a second of the second conductive contacts.

2. The substrate package of claim 1, wherein the second RDL further provides at least part of an electrical path between a third of the second conductive contacts and a second of the third conductive contacts.

3. The substrate package of claim 1, wherein the first dielectric material and the second dielectric material are the same.

4. The substrate package of claim 1, wherein the first dielectric material and the second dielectric material are different.

5. The substrate package of claim 1, further comprising a first lateral layer of glass with through glass vias (TGVs) in the first region.

6. The substrate package of claim 5, wherein the first lateral layer of glass has a thickness in a range of 100 microns+/−10% to 1.5 millimeters+/−10%.

7. The substrate package of claim 5, wherein the first lateral layer of glass extends underneath the second region, and further comprising:
a cavity floor formed in the first lateral layer of glass underneath the second region; and
wherein the second RDL in the second region is operationally coupled to some of the TGVs in the cavity floor.

8. The substrate package of claim 1, further comprising a lateral layer of epoxy in the first RDL.

9. The substrate package of claim 1, wherein the first RDL and the second RDL comprise copper.

10. The substrate package of claim 5, further comprising a second layer of glass with through glass vias in the second region.

11. The substrate package of claim 1, further comprising:
a portion of the first region that extends underneath the second region; and
a cavity with a cavity floor formed below the second region in the portion of the first region.

12. The substrate package of claim 11, wherein the second region is attached via a bond film in the cavity floor.

13. The substrate package of claim 11, wherein the second region is attached via hybrid bonding or solder bumps in the cavity floor.

14. The substrate package of claim 13, wherein the second RDL is operationally coupled to the first RDL in the cavity floor.

15. The substrate package of claim 11, wherein the second RDL is operationally coupled to the third arrangement of conductive contacts via the portion of the first region.

16. The substrate package of claim 1, further comprising:
a layer of a third dielectric material between the lower surface and the first region and the second region.

17. The substrate package of claim 1, further comprising:
a first integrated circuit die attached to the first conductive contacts and a first portion of the second conductive contacts; and
a second integrated circuit die attached to a second portion of the second conductive contacts.

18. A package assembly comprising the substrate package of claim 1, further comprising:
a first integrated circuit die attached to the first conductive contacts and a first portion of the second conductive contacts; and
a second integrated circuit die attached to a second portion of the second conductive contacts; and
solder balls attached to the third conductive contacts.

19. The package assembly of claim 18, further comprising a printed circuit board (PCB), the PCB attached to the solder balls.

20. A method, comprising:
fabricating a substrate package having a layer of dielectric material between and upper surface and a lower surface, wherein the dielectric material has therein first redistribution layers (RDL) at a pitch greater than 9 microns+/−20%, and wherein the upper surface comprises a first arrangement of first conductive contacts at a first pitch and a second arrangement of second conductive contacts at a second pitch;
creating a cavity with a cavity floor in the dielectric material;
fabricating an organic bridge component having second RDL at a pitch of three microns+/−10% or less; and
attaching the organic bridge component to the cavity floor to thereby create electrical paths between individuals of the second conductive contacts at the upper surface.
